(19) United States
(12) Patent Application Publication
(10) Pub. No.: US 2007/0231974 A1
(43) Pub. Date: Oct. 4, 2007

(54) THIN FILM TRANSISTOR HAVING COPPER LINE AND FABRICATING METHOD THEREOF

(76) Inventors: Hsien-Kun Chiu, Taipei City (TW); Yung-Chia Kuan, Taipei City (TW); Kuo-Sheng Sun, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,494

(22) Filed: Mar. 30, 2006

(51) Int. Cl. H01L 21/84; H01L 29/788; H01L 21/00

(52) U.S. Cl. 438/149; 257/315

(57) ABSTRACT

A thin film transistor having a substrate, a bottom layer, a gate, a gate-insulating layer, a channel layer and a source/drain, is provided. The bottom layer is disposed on the substrate. The copper gate is disposed on the bottom layer. The gate-insulating layer covers the copper gate and the bottom layer. The channel layer is disposed on the gate-insulating layer and above the gate. The source/drain is disposed at two sides of the channel layer which is above the gate. By disposing the bottom layer, the problem of poor adhesion between the copper gate and the substrate can be solved.

### BACKGROUND OF THE INVENTION

1. Field of Invention

The present invention relates to an active device and the fabricating method thereof. More particularly, the present invention relates to a thin film transistor (TFT) and a fabricating method thereof.

2. Description of Related Art

In recent years, due to the mature optoelectronic technology and the advanced semiconductor fabrication technology, the flat panel display is developing rapidly. The thin film transistor liquid crystal display (TFT-LCD) gradually becomes a mainstream of the display products, owing to its advantages, including low-voltage operation, high operating speed, light weight, and compactness.

TFT-LCD is mainly composed of a TFT array substrate, a color filter substrate and a liquid crystal layer between the two substrates. The TFT array substrate has a plurality of thin film transistors (TFTs) arranged in a matrix, and each TFT is electrically connected to a pixel electrode. The TFTs are used as switching elements of the liquid crystal display unit. Therein, each TFT is formed by sequentially fabricating a gate, a channel layer and a source/drain on an insulating substrate.

FIG. 1 shows a schematic cross-sectional view of a conventional TFT. Referring to FIG. 1, a TFT 100 is formed by the following steps: forming a gate 120 on a substrate 110; forming a gate-insulating layer 130 to cover the gate 120; forming a semiconductor material layer (not shown) and an ohmic contact material layer (not shown) sequentially, and then defining a semiconductor layer 142 and an ohmic contact layer 144 through lithographing; forming a source 150a/drain 150b; and then etching the ohmic contact layer 144 between the source 150a/drain 150b to expose the semiconductor layer 142.

However, when TFT 100 is applied in a large-sized liquid crystal display, serious resistance-capacitance time delay (RC time delay) will appear. In the TFT 100, the metal used in the gate 120 and source 150a/drain 150b is mostly either Cr, Al, or Mo, and the metals such as Cr, Al, and Mo have large resistance coefficients. For example, the resistance coefficient of aluminum is up to 3.5 μΩ-cm. As the signal transfer rate of the circuit lies on the product of the resistance (R) and the capacitance (C), the larger the RC value is, the smaller the signal transfer rate is. Therefore, when the size of the liquid crystal display becomes larger and larger, and the material of the metal lines has a large resistance coefficient, the resultant RC time delay will limit the developments of the large-sized liquid crystal display significantly.

To solve the above phenomenon of RC time delay, copper, a metal of a low resistance coefficient (the resistance coefficient of Cu is only 1.7μΩ-cm), is used to replace the above metals of high resistance coefficients (such as Cr, Al, Mo, etc.). But copper has a poor adhesion to the insulating substrate, and may peel off easily. Thus, the application of Cu as the metal gate is restricted. As discussed above, another metal layer is proposed to be used as an adhesion layer between Cu and the insulating substrate.

FIG. 2 shows a schematic cross-sectional view of another conventional TFT, by forming the gate with two metal layers. Referring to FIG. 2, the structure of a TFT 200 is substantially the same as the TFT 100 of FIG. 1. The TFT 200 has a substrate 210, a gate 220, a gate-insulating layer 230, a semiconductor layer 242, an ohmic contact layer 244 and a source 250a/drain 250b. It is noted that, the gate 220 as shown in FIG. 2 is composed of a copper metal layer 222 and another metal layer 224, and the metal layer 224 may be made of Mo or Ti. Hence, the copper metal layer 222 may be adhered to the substrate 210 through the assistance of the metal layer 224.

However, since the gate 220 as shown in FIG. 2 contains least two different metals, it is not easy to choose an etching solution or an etching gas suitable for both metals. Besides, during the etching process, it will cause a poor taper angle of the gate 220, or incomplete etching of the metal layer 224. Furthermore, the metal layer 224 as shown in FIG. 2 may also be replaced by an indium tin oxide (ITO) layer. But an undercut may occur in the ITO layer after the etching process, and the yield of the TFT will be reduced.

### SUMMARY OF THE INVENTION

Accordingly, the present invention is directed to provide a thin film transistor (TFT), which is useful for solving the poor adhesion problem between the copper gate and the substrate and various problems caused from the copper gate with two metal layers.

The present invention is further directed to provide a method for fabricating the TFT, which is useful for solving the problem of poor adhesion between the copper gate and the substrate, and increasing the yield of the TFT.

To achieve the above or other objects, the present invention provides a TFT, which comprises a substrate, a bottom layer, a gate, a gate-insulating layer, a channel layer and a source/drain. The bottom layer is disposed on the substrate. The copper gate is disposed on the bottom layer. The gate-insulating layer covers the copper gate and the bottom layer. The channel layer is disposed on the gate-insulating layer and above the gate. The source/drain is disposed at two sides of the channel layer which is above the gate.

In one embodiment of the present invention, the material of said bottom layer is selected from the group consisting of SiNₓ, SiON, SiO₂, TiO₂, Al₂O₃, ZrO₂, Nb₂O₅, Ta₂O₅, BaTiO₃, PbZrTiO₇ and the combinations thereof.

In one embodiment of the present invention, the thickness of said bottom layer is between 50-300 nm.

In one embodiment of the present invention, the material of said gate-insulating layer is the same as the material of the bottom layer.

In one embodiment of the present invention, the material of said gate-insulating layer is different from the material of the bottom layer.

In one embodiment of the present invention, said channel layer comprises a semiconductor layer and an ohmic contact layer, and the ohmic contact layer is located on the semiconductor layer.

To achieve the above or other objects, the present invention further provides a method for fabricating the TFT, which comprises the following steps: providing a substrate; forming a bottom layer on the substrate; forming a copper gate on the bottom layer; forming a gate-insulating layer on the substrate and covering the copper gate and the bottom layer; forming a channel layer on the gate-insulating layer and above the gate; and forming a source/drain at two sides of the channel layer which is above the gate.

In one embodiment of the present invention, the method of forming the bottom layer on the substrate comprises a chemical vapor deposition.

In one embodiment of the present invention, the material of said bottom layer material is selected from the group consisting of SiNₓ, SiON, SiO₂, TiO₂, Al₂O₃, ZrO₂, Nb₂O₅, Ta₂O₅, BaTiO₃, PbZrTiO₇ and the combinations thereof.

In one embodiment of the present invention, the thickness of said bottom layer is between 50-300 nm.

In one embodiment of the present invention, the material of said gate-insulating layer is the same as the material of the bottom layer.

In one embodiment of the present invention, the material of said gate-insulating layer is different from the material of the bottom layer.

In one embodiment of the present invention, the method for forming the copper gate on the bottom layer comprises the following steps: forming a copper layer on the bottom layer; and patterning the copper layer. The method for forming the copper material layer includes evaporation or sputtering.

In one embodiment of the present invention, the method for forming the channel layer on the gate-insulating layer and above the copper gate comprises the following steps: forming a semiconductor material layer and an ohmic contact material layer on the gate-insulating layer; and patterning the semiconductor material layer and the ohmic contact material layer.

In one embodiment of the present invention, the method for forming the source/drain at two sides of the channel layer comprises the following steps: forming a source/drain material layer on the channel layer; and patterning the source/drain material layer.

In one embodiment of the present invention, after forming the source/drain at two sides of the channel layer which is above the gate, an etching back process is further performed so as to remove the ohmic contact layer and a part of the semiconductor layer which are above the gate.

In the present invention, the copper gate is disposed over the substrate with the bottom layer in-between, such that peeling of the copper gate from the substrate may be prevented. The copper gate may be formed by etching only one metal, and it is easy to choose a suitable etching solution or etching gas. Moreover, the taper angle of the formed copper gate is satisfactory. Besides, the bottom layer may also be used as a barrier layer, so as to solve the diffusion problem of the metal atoms from the copper gate into the substrate.

In order to the make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a schematic cross-sectional view of a conventional thin film transistor (TFT).

FIG. 2 shows a schematic cross-sectional view of another conventional TFT having a gate with two metal layers.

FIG. 3 shows a schematic cross-sectional view of a TFT according to a preferred embodiment of the present invention.

FIGS. 4A˜4I show schematic cross-sectional views of the process steps of the method for fabricating a TFT according a preferred embodiment of the present invention.

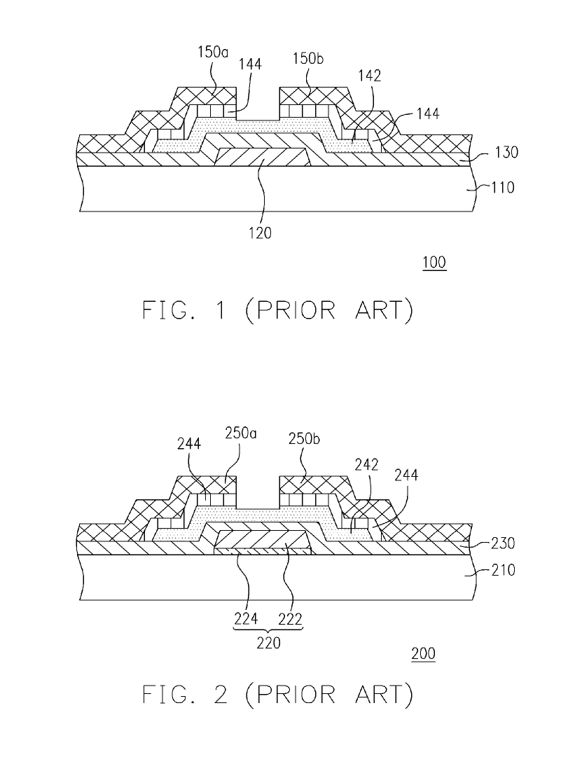

### DESCRIPTION OF EMBODIMENTS

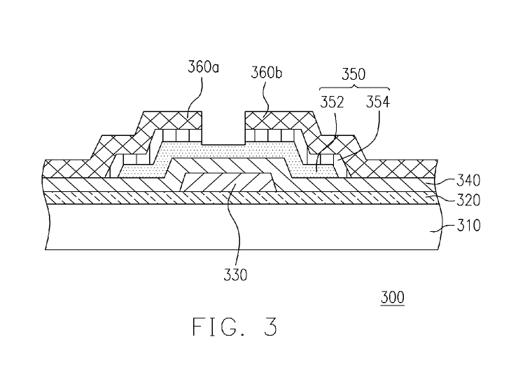

FIG. 3 shows a schematic cross-sectional view of a thin film transistor (TFT) according to a preferred embodiment of the present invention. Referring to FIG. 3, the TFT 300 comprises a substrate 310, a bottom layer 320, a copper gate 330, a gate-insulating layer 340, a channel layer 350 and a source 360a/drain 360b. The bottom layer 320 is disposed on the substrate 310. The copper gate 330 is disposed on the bottom layer 320. The gate-insulating layer 340 covers the copper gate 330 and the bottom layer 320. The channel layer 350 is disposed on the gate-insulating layer 340 and above the copper gate 330. The source 360a/drain 360b is disposed at two sides of the channel layer 350 which is above the copper gate 330.

Referring to FIG. 3, the substrate 310 is, for example, a glass substrate or a quartz substrate. And a bottom layer 320 is disposed on the substrate 310. In one embodiment, the material of the bottom layer 320 is, for example, selected from the group consisting of SiNₓ, SiON, SiO₂, TiO₂, Al₂O₃, ZrO₂, Nb₂O₅, Ta₂O₅, BaTiO₃, PbZrTiO₇ and the combinations thereof. Preferably, the material of the bottom layer 320 may be SiNₓ, which has a good transparent property, so that the bottom layer 320 will not influence the light transmittance of the liquid crystal display panel (not shown).

The copper gate 330 is disposed on the bottom layer 320. In one embodiment of the present invention, the material of the copper gate 330 may be metal copper (Cu), for example. Due to the poor adhesion between Cu and glass, if the copper gate 330 is formed directly on the substrate 310 by sputtering, the copper gate 330 will easily peel off from the substrate 310. Therefore, by disposing said bottom layer 320, the peeling problem of the copper gate 330 from the substrate 310 may be improved. More particularly, when the copper gate 330 is formed on the bottom layer 320 by sputtering, the adhesion force between the copper gate 330 and the bottom layer 320 may be increased with conditions of high temperature and high DC voltage, and the copper gate 330 may be well disposed over the substrate 310 through the bottom layer 320. Besides, in one embodiment of the present invention, the thickness of the bottom layer 320 is between about 50˜300 nm. The bottom layer 320 also functions as a barrier layer to prevent the copper atoms in the copper gate 330 from diffusing into the substrate 310.

The gate-insulating layer 340 covers the copper gate 330 and the bottom layer 320. In one embodiment of the present invention, the material of the gate-insulating layer 340 and the material of the bottom layer 320 may be the same or may be different. Especially, because the gate-insulating layer 340 and the bottom layer 320 together wrap around the copper gate 330, the structure may prevent the diffusion of the copper atoms effectively.

Furthermore, as shown in FIG. 3, in one embodiment of the present invention, the channel layer 350 comprises a semiconductor layer 352 and an ohmic contact layer 354 disposed on the semiconductor layer 352. The semiconductor layer 352 is, for example, an amorphous silicon layer or a polysilicon layer, and the ohmic contact layer 354 is a doped N⁺ amorphous silicon layer or a doped N⁺ polysilicon layer. The source 360a/drain 360b is disposed at two sides of the channel layer 350, and the material of the source 360a/drain 360b is, for example, a metal.

As described above, in the TFT 300 of the present invention, the copper gate 330 is disposed over the substrate 310 with the bottom layer 320 in-between, and the bottom layer 320 functions as an adhesion layer to prevent the copper gate 330 from peeling off from the substrate 310. Besides, the bottom layer 320 may function as a barrier layer, to solve the problem of the metal atoms diffusing from the copper gate 330 into the substrate 310. Furthermore, the gate-insulating layer 340 and the bottom layer 320 together wrap around the copper gate 330, such that the diffusion of the metal atoms in the copper gate 330 may be prevented effectively.

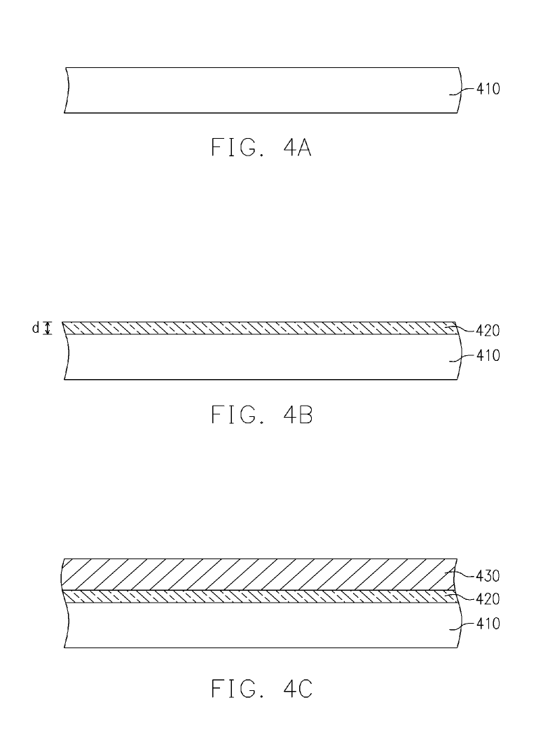

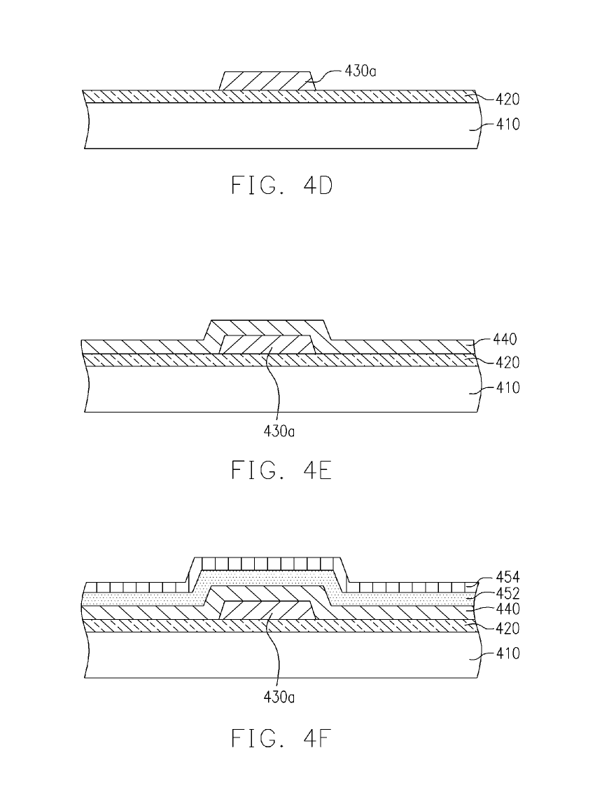

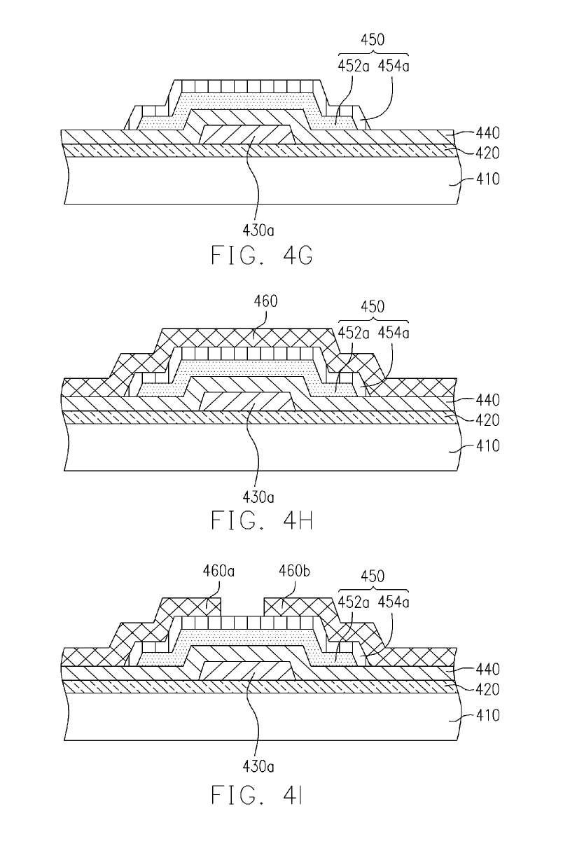

FIGS. 4A˜4I show schematic cross-sectional views of the process steps of the method for fabricating a TFT according to a preferred embodiment of the present invention.

Referring to FIGS. 4A˜4I, a substrate 410 is provided, as shown in FIG. 4A. The substrate 410 may be a glass substrate or a quartz substrate.

And then, a bottom layer 420 is formed on the substrate 410, as shown in FIG. 4B. In one embodiment of the present invention, the method for forming the bottom layer 420 on the substrate 410 is, for example, chemical vapor deposition. Preferably, the bottom layer 420 is formed by plasma enhanced chemical vapor deposition (PECVD), and the thickness d of the formed bottom layer 420 is between about 50-300 nm.

Especially, the material of the bottom layer 420 is, for example, selected from the group consisting of SiNₓ, SiON, SiO₂, TiO₂, Al₂O₃, ZrO₂, Nb₂O₅, Ta₂O₅, BaTiO₃, PbZrTiO₇, or the combinations thereof. Preferably, the material of the bottom layer 420 may be SiNₓ.

When SiNₓ is used as the material of the bottom layer 420, and PECVD is used to form the bottom layer 420, the conditions of forming SiNₓ film are, for example, described as below. Therein, the plasma gas is, for example, Ar, and the flow is between 250˜5,000 sccm, and the RF power of the plasma is set, for example, between 50˜2,000 W. The pressure of the reaction chamber, for example, is set between 1˜5 torr, and the reaction temperature is, for example, between 260˜310° C. The reaction gases are, for example, SiH₄, NH₃, N₂, etc., and the flow of SiH₄ is, for example, between 100˜2,000 sccm, the flow of NH₃ is, for example, between 300˜1,500 sccm, and the flow of N₂ is, for example, between 750˜7,500 sccm.

Then, a copper gate 430a is formed on the bottom layer 420, as shown in FIG. 4D. In one embodiment of the present invention, the method for forming the copper gate 430a on the bottom layer 420 comprises the steps as shown in FIGS. 4C˜4D.

At first, referring to FIG. 4C, a copper layer 430 is formed on the bottom layer 420. The method for forming the copper layer 430 may be evaporation or sputtering. Usually, if the material of the bottom layer 420 is SiNₓ, the adhesion between Cu and SiNₓ is poor. Therefore, in one embodiment of the present invention, when the copper layer 430 is formed by sputtering, conditions of high temperature and high DC voltage are used, so as to make the copper layer 430 be well adhered to the bottom layer 420. Therein, the sputtering temperature is, for example, between 100˜300° C., and the DC power is, for example, between 10˜40 kW.

And then, the copper layer 430 is patterned to form the copper gate 430a as shown in FIG. 4D. The method for patterning the copper layer 430 is, for example, a conventional photolithography process. At first, a patterned photoresist layer (not shown) is formed on the copper layer 430, and then the copper gate 430a is formed by etching the copper layer 430 using the patterned photoresist layer as an etching mask. It should be noted that, during forming the copper gate 430a according to the present invention, only the copper layer 430 needs to be etched. Therefore, compared with the TFT 200 as shown in FIG. 2 in the conventional technology, the present invention needs not to etch different kinds of metals. Accordingly, it is easy to choose a suitable etching solution. And the taper angle of the copper gate 430a may be around 60 degrees, and no undercut will occur during the etching process.

And then, a gate-insulating layer 440 is formed on the substrate 410, and the gate-insulating layer 440 covers the copper gate 430a and the bottom layer 420, as shown in FIG. 4E. In one embodiment of the present invention, the method for forming the gate-insulating layer 440 is, for example, chemical vapor deposition. Besides, the material of the gate-insulating layer 440 and the material of the bottom layer 420 are, for example, the same or different. It should be noted that, the copper gate 430a is wrapped by the gate-insulating layer 440 and the bottom layer 420, and the diffusion of the metal in the copper gate 430a may be prevented. Especially, when the copper gate 430a is made of copper metal, it can prevent the diffusion of copper atoms more effectively, and avoid the adverse influences to the electrical property of the subsequently formed channel layer 450.

Then, a channel layer 450 is formed on the gate-insulating layer 440 and above the copper gate 430a, as shown in FIG. 4G. In one embodiment of the present invention, the method for forming the channel layer 450 on the gate-insulating layer 440 and above the copper gate 430a comprises the steps as shown in FIGS. 4F˜4G.

At first, referring to FIG. 4F, a semiconductor material layer 452 and an ohmic contact material layer 454 are formed on the gate-insulating layer 440 sequentially. In one embodiment, the method for forming the semiconductor material layer 452 and the ohmic contact material layer 454 is, for example, chemical vapor deposition. The material of the semiconductor material layer 452 is, for example, amorphous silicon or polysilicon, and the material of the ohmic contact material layer 454 is, for example, doped N⁺amorphous silicon or N⁺polysilicon.

Then, the semiconductor material layer 452 and the ohmic contact material layer 454 are patterned to form a channel layer 450 as shown in FIG. 4G. The channel layer 450 includes a semiconductor layer 452a and an ohmic contact layer 454a. The method for patterning the semiconductor material layer 452 and the ohmic contact material layer 454 may be a conventional lithographing process, and will not be described in details herein.

Afterwards, a source 460a/drain 460b is formed at two sides of the channel layer 450 which is above the copper gate 430a, as shown in FIG. 4I. In one embodiment of the present invention, the method for forming the source 460a/drain 460b at two sides of the channel layer 450 which is above the copper gate 430a comprises the steps as shown in FIGS. 4H˜4I.

At first, as shown in FIG. 4H, a source/drain material layer 460 is formed on the channel layer 450. The method for forming the source/drain material layer 460 is, for example, sputtering, and the material of the source/drain material layer 460 is, for example, a metal.

Then, the source/drain material layer 460 is patterned to form the source 460a/drain 460b as shown in FIG. 4I. The patterning process may be a conventional lithographing process, and will not be described herein in details. It should be noted that, in one embodiment of the present invention, after forming the source 460a/drain 460b at two sides of the channel layer 450, an etching back process is further performed (not shown) to remove the ohmic contact layer 454a and a part of the semiconductor layer 452a which are above the copper gate 430a, so as to form the TFT 300 as shown in FIG. 3.

As described above, the TFT of the present invention and the method for fabricating thereof has the following advantages:

(1) By disposing the bottom layer, the TFT of the present invention can solve the problem of poor adhesion between the copper gate and the substrate, and prevented peeling of the copper gate from the substrate. The bottom layer functions as a barrier layer to prevent the metal atoms in the copper gate from diffusing into the substrate.

(2) By disposing the bottom layer, it is unnecessary to form the copper gate with different metal layers. Therefore, it is easy to choose an etching solution and an etching gas suitable for etching the gate.

(3) According to the method for fabricating the TFT in the present invention, when performing an etching process to form the gate, the taper angle of the copper gate is satisfactory, and undercuts will not occur in the bottom layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor (TFT), comprising:
a substrate;
a bottom layer disposed on the substrate;
a copper gate disposed on the bottom layer, wherein a material of the copper gate comprises copper;
a gate-insulating layer covering the copper gate and the bottom layer;
a channel layer disposed on the gate-insulating layer and above the gate; and
a source/drain disposed at two sides of the channel layer which is above the gate.

2. The TFT as claimed in claim 1, wherein a material is selected from a group consisting of SiNₓ, SiON, SiO₂, TiO₂, Al₂O₃, ZrO₂, Nb₂O₅, Ta₂O₅, BaTiO₃, PbZrTiO₇ and combinations thereof.

3. The TFT as claimed in claim 1, wherein a thickness of the bottom layer is between 50˜300 nm.

4. The TFT as claimed in claim 1, wherein a material of the gate-insulating layer is the same as that of the bottom layer.

5. The TFT as claimed in claim 1, wherein a material of the gate-insulating layer is different from that of the bottom layer.

6. The TFT as claimed in claim 1, wherein the channel layer comprises a semiconductor layer and an ohmic contact layer on the semiconductor layer.

7. A method for fabricating the TFT, comprising:
providing a substrate;
forming a bottom layer on the substrate;
forming a copper gate on the bottom layer;
forming a gate-insulating layer on the substrate, wherein the gate-insulating layer covers the copper gate and the bottom layer;
forming a channel layer on the gate-insulating layer and above the gate; and
forming a source/drain at two sides of the channel layer which is above the gate.

8. The method for fabricating the TFT as claimed in claim 7, wherein a method for forming the bottom layer on the substrate comprises chemical vapor deposition.

9. The method for fabricating the TFT as claimed in claim 7, wherein a material of the bottom layer is selected from a group consisting of SiNₓ, SiON, SiO₂, TiO₂, Al₂O₃, ZrO₂, Nb₂O₅, Ta₂O₅, BaTiO₃, PbZrTiO₇ and combinations thereof.

10. The method for fabricating the TFT as claimed in claim 7, wherein a thickness of the bottom layer is between 50˜300 nm.

11. The method for fabricating the TFT as claimed in claim 7, wherein a material of the gate-insulating layer is the same as that of the bottom layer.

12. The method for fabricating the TFT as claimed in claim 7, wherein a material of the gate-insulating layer is different from that of the bottom layer.

13. The method for fabricating the TFT as claimed in claim 7, wherein a method for forming the copper gate on the bottom layer comprises:
forming a copper layer on the bottom layer; and
patterning the copper layer.

14. The method for fabricating the TFT as claimed in claim 13, wherein a method for forming the copper layer comprises evaporation or sputtering.

15. The method for fabricating the TFT as claimed in claim 7, wherein a method for forming the channel layer on the gate-insulating layer and above the copper gate comprises:
forming a semiconductor material layer and an ohmic contact material layer on the gate-insulating layer sequentially; and
patterning the semiconductor material layer and the ohmic contact material layer.

16. The method for fabricating the TFT as claimed in claim 7, wherein a method for forming the source/drain at two sides of the channel layer which is above the copper gate comprises:
forming a source/drain material layer on the channel layer; and
patterning the source/drain material layer.

17. The method for fabricating the TFT as claimed in claim 7, wherein after forming the source/drain at two sides of the channel layer which is above the gate, an etching back process is further performed to remove the ohmic contact layer and a part of the semiconductor layer which are above the gate.
